(19) United States
(12) Patent Application Publication
(10) Pub. No.: US 2020/0288594 A1
(43) Pub. Date: Sep. 10, 2020

(54) FLUID METER, ENERGY STORAGE DEVICE FOR A FLUID METER, AND METHOD

(71) Applicant: DIEHL METERING GMBH, ANSBACH (DE)

(72) Inventor: MALTE BAER, NUERNBERG (DE)

(21) Appl. No.: 16/808,692

(22) Filed: Mar. 4, 2020

(30) Foreign Application Priority Data
Mar. 7, 2019 (DE) 102019001590

(51) Int. Cl. H05K 5/06; H05K 5/02; H02J 50/10; G01F 15/14

(52) U.S. Cl. CPC H05K 5/064; G01F 15/14; H02J 50/10; H05K 5/0247

(57) ABSTRACT

A fluid meter with an electronic unit has a housing in which an electronic device and an energy storage device are disposed. The electronic device and the energy storage device are potted separately with a potting compound in a respective potting housing and they are coupled with one another either via a cable connection or via an inductive energy transmission interface.

### CROSS-REFERENCE TO RELATED APPLICATION

This application claims the priority, under 35 U.S.C. § 119, of German patent application DE 10 2019 001 590, filed Mar. 7, 2019; the prior application is herewith incorporated by reference in its entirety.

### BACKGROUND OF THE INVENTION

### Field of the Invention

The invention relates to a fluid meter with an electronic unit, comprising a housing in which an electronic device and an energy storage device are arranged. The energy storage device is associated with and supplies the electronic device.

Fluid meters of this type are used in different fields of application. The most well-known are water meters. A fluid meter of this type comprises an electronic unit, often also described as an arithmetic unit, with an electronic device which processes the measurement values recorded via a corresponding measuring section and reproduces them by means of a display device, usually a display. In order to operate the electronic device, which also includes the measuring sensors, an energy storage device, i.e. a battery module, is also provided in the housing, which battery module is coupled with the electronic device in an energy-transmitting manner, usually carried out via a corresponding cable connection. Alternatively, an inductive energy transmission interface is also provided.

Fluid meters are sometimes configured so that they can also be assembled submerged in the fluid, i.e. under water, for example. This requires the housing of the electronic unit to be hermetically sealed, so as to prevent even the slightest amount of fluid being able to enter into the housing. A sealing approach of this type is extremely complex with respect to the specific sealing requirements.

The energy storage device sometimes has to be replaced if the meter has been in use for a long time. For this purpose, it is necessary to open the meter housing, be it fully or be it only in the area of a battery opening via which it is possible to access the energy storage device. However, in each case the hermetically sealed arrangement is thereby affected, since the housing is being either fully or locally opened. After replacing the energy storage device, it is necessary to re-establish the seal, which requires a considerable amount of effort.

### SUMMARY OF THE INVENTION

It is accordingly an object of the invention to provide a fluid meter, which overcomes the above-mentioned and other disadvantages of the heretofore-known devices and methods of this general type and which provides for a fluid meter that is improved in that regard.

With the above and other objects in view there is provided, in accordance with the invention, a fluid meter with an electronic unit, the fluid meter comprising:

a housing;

an electronic device disposed in the housing;

an energy storage device disposed in the housing, the energy storage device being associated with, and configured to supply, the electronic device;

the electronic device and the energy storage device being potted separately in a potting compound; and

a cable connection or an inductive energy transmission interface coupling the energy storage device with the electronic device.

In other words, the objects of the invention are achieved by the invention in that the electronic device and the energy storage device are potted separately in a potting compound, preferably in one potting housing respectively, and in that they are coupled with one another either via a cable connection or via an inductive energy transmission interface.

In the case of the fluid meter according to the invention or the electronic unit according to the invention, a separately potted electronic device and a separately potted energy storage device, i.e. a separately potted battery unit, is provided, which can be produced in a prefabricated manner as separate potting assemblies, potted in a completely sealed manner and subsequently can be installed in the housing as part of the assembly. The coupling for the energy transmission can take place via a cable connection, for which purpose both are connected to one another via one or a plurality of connection cables. These connection cables can be connected to the corresponding terminals, which are sufficiently sealed, on the electronic device or on the energy storage device, the connected ends preferably being embedded in the potting compound of the electronic device or respectively the energy storage device. Alternatively to the cable connection, providing an inductive energy transmission interface is also conceivable, which means that the appropriate transmission elements are provided, on the one hand, in the potted electronic device and, on the other hand, in the potted energy storage device and are positioned relative to one another in the assembly position in such a way that an energy transmission is possible.

As a result of the direct, separate potting of the two devices and in the case of the two being coupled via a cable connection, in the context of which a fluid-resistant cable is of course suitably used, a maximum fluid resistance or respectively media resistance is guaranteed when the fluid meter is produced and supplied or rather installed for the first time. Full protection against the ingress of fluid is provided by the potting in the critical regions of the electronic device or respectively the energy storage device, even in the case of an underwater assembly. On the part of the housing which accommodates the two devices, ideally no associated sealing means have to be provided since, as a result of the potting, the housing can be flooded with the fluid, even when assembling, without the functionality being even slightly impaired. Of course, it is possible to provide a simple housing seal, but under no circumstances does this have to meet the high requirements of a complete media seal.

In addition to the complete sealing of the relevant components, a particular advantage of the inventive fluid meter is also that it is possible to replace the energy storage device if necessary. This is because it is only necessary to remove the energy storage device after opening the housing, for which purpose either the cable connection must be cut through in the case of a cable connection, after which a new potted energy storage device is inserted and is connected, with its cable section, to the remaining cable section which comes from the electronic device, wherein of course this connection must be or must become sealed, or, in the case of an inductive energy transmission, no additional seal is required, but instead merely a replacement.

However, under no circumstances is it necessary to carry out complex, comprehensive housing sealing in addition to the replacement, since all components involved are completely potted again, and even in the case of a newly connected cable connection, this connection region is sealed. The sealing in this region can be achieved by using corresponding sealed or self-sealed cable connectors, such as an insulation-displacement connector, for example. Using such a connector guarantees a sufficiently high-quality seal, such that an underwater assembly is indeed possible again simply by using such a connector. Of course, it is possible to also separately seal or to pot this connecting device or rather this insulation-displacement connector again retrospectively, further details of which will be added below.

In addition to the fluid meter itself, the invention also relates to an energy storage device for a fluid meter of the type described previously, which is suitable for replacing an energy storage device which is already present in the fluid meter. This energy storage device is distinguished in that one or a plurality of storage cells are accommodated in a potting housing and are coupled with a cable section, which is routed outside of the housing, or an inductive energy transmission interface component which is arranged in the housing, wherein the storage cells and the end of the cable connection, which end is located in the housing, or the energy transmission interface component are potted with a potting compound, wherein a connecting device, for connecting to a cable section which is arranged on the electronic device of the fluid meter and which remains after the energy storage device which is to be replaced is removed, is provided on the cable section.

This energy storage device is thus distinguished in that it is completely potted, in other words the storage cells are completely embedded in the potting housing. Either a cable section protrudes from the potting compound, on which cable section a corresponding connecting device, for connecting to the corresponding cable section of the electronic device, is arranged in an already preconfigured manner, in other words only the cable section thereof still has to be connected to the connecting device. Alternatively, the energy storage device can also comprise a potted interface component for an inductive energy transmission.

This energy storage device can thus be completely preconfigured, so that any replacement can take place in a very simple manner.

The connecting device is preferably an insulation-displacement connector which makes it possible to in turn connect the cable sections preferably in a media-tight or fluid-tight manner.

Furthermore, the invention relates to a method for replacing an energy storage device of a fluid meter of the type described previously, using an energy store of the type described previously.

Within the context of this method, provision can be made for a cable connection of the fluid meter or of the electronic unit which connects the potted electronic device and the potted energy storage device to be disconnected, and for the connecting device which is arranged on the cable section of the new energy storage device to be connected to the remaining cable section of the electronic device. If the fluid meter which is to be made functional again or the electronic unit which is to be repaired consequently has a cable connection, this is disconnected in a simple manner, i.e. cut through, and then, after inserting the new energy storage device, the connecting device which is provided on said energy storage device is connected to the free cable end of the electronic device. If an insulation-displacement connector is used, the free cable end is consequently connected thereto.

If this connecting device is not already fluid-tight or media-tight at origin, as may be the case for an appropriately configured insulation-displacement connector, for example, it is possible to pot the connecting device with a potting compound after connecting the two cable sections, wherein an insulation-displacement connector of this type can of course additionally be potted again.

The connecting device can be inserted into a housing region which is subsequently potted with the potting compound. In the housing of the electronic unit, an associated housing region, for example a housing region which is spatially delimited by associated walls, can therefore already be provided, into which housing region the connecting device is inserted and which is subsequently filled with the potting compound. The connecting device is then embedded in or cast firmly on the housing via the potting compound.

Alternatively, it is possible to place a separate housing around the connecting device, for example a housing made of two half-shells which are either separate or are pivotally articulated to one another, and subsequently to fill this housing with the potting compound, i.e. to use the housing as a casting mold. This housing then optionally remains on the potted connecting device.

Alternatively to potting, it is also possible to arrange the connecting device in a region inside the housing of the electronic unit in which an air bubble forms in the assembly position under fluid. The connecting device is thus positioned in a housing region in which, if the fluid meter which is once again functional is put under water again, an air bubble forms so that the connecting device, which, as described, is suitably equipped at origin with a high-quality media seal, does not come into contact with the fluid, i.e. water, for example. A sufficient, still greater level of safety can also be achieved in this way.

In the event that the fluid meter which is to be made functional again or the electronic unit possesses an energy transmission interface, it is only necessary to replace the old energy storage device with a new one and then to reconnect the housing in order to repair it. When carrying out the replacement, it is of course important to ensure that the energy transmission interface component of the new energy storage device is positioned correctly on the electronic device with respect to the corresponding component. This can come to pass in a simple manner by providing a corresponding guide or receptacle on the housing side which makes it possible to position the energy storage device in a precise and defined manner.

In addition to the method according to the invention itself, the invention also relates to a fluid meter which has been produced in line with the method according to the invention described previously, i.e. has been made functional again. This fluid meter is distinguished in that the potted electronic device and the potted energy storage device are connected via a cable connection which has two cable sections that are connected via a connecting device, of which cable sections one is connected to the electronic device and the other to the energy storage device.

If necessary, the connecting device can additionally be potted with a potting compound, for which purpose it is either arranged in a housing region which is filled with the potting compound or, alternatively, a housing can also be arranged around the connecting device, which housing is subsequently filled with the potting compound.

Furthermore, provision can alternatively or additionally be made for the connecting device to be arranged in a region inside the housing of the fluid meter in which an air bubble forms in the assembly position under fluid.

Other features which are considered as characteristic for the invention are set forth in the appended claims.

Although the invention is illustrated and described herein as embodied in fluid meter, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 shows a schematic plan view depiction of an electronic unit or an arithmetic unit of a fluid meter according to the invention with an open housing prior to it being newly repaired by replacing the energy storage device;

FIG. 2 shows the underside view of the electronic device and the energy storage device which is connected thereto via a cable connection;

FIG. 3 shows the arrangement in accordance with FIG. 1 during the replacement process and the disconnection of the cable connection;

FIG. 4 shows a perspective view of a new energy storage device according to the invention which is provided for the replacement;

FIG. 5 shows the energy storage device from FIG. 4 in a different perspective view;

FIG. 6 shows the arrangement during the connection process of the energy storage device to the electronic device;

FIG. 7 shows the newly repaired electronic unit with an open housing;

FIG. 8 shows the electronic unit from FIG. 7, wherein the electronic device and the energy storage device are accommodated in the other housing half;

FIG. 9 shows the possibility of subsequently potting the connecting device;

FIG. 10 shows a sectioned schematic depiction of the repaired fluid meter; and

FIG. 11 is view similar to FIG. 8 illustrating an embodiment in which the energy transfer is effect by way of wireless, inductive transfer.

### DETAILED DESCRIPTION OF THE INVENTION

Referring now to the figures of the drawing in detail and first, particularly, to FIG. 1 thereof, there is shown an electronic unit 1 as part of a fluid meter according to the invention, for example a water meter in the form of a domestic water meter or industrial water meter. The electronic unit 1 comprises a housing 2 which preferably consists of two housing shells. Only the one housing shell 2a is shown in FIG. 1. An exemplary second housing shell 2b is shown in FIG. 8, in an open housing state.

An electronic device 3 is located in the interior of the housing 2. The electronic device comprises all the relevant measuring and processing elements, such as sensors, calculation and processing device or specific control device, as well as a display 4. Moreover, an energy storage device 5 is also provided in the housing 2, for example in the form of a correspondingly powerful battery which comprises a corresponding number of energy storage cells or modules and is connected to the electronic device 3 via a cable connection 6. As an alternative to a cable connection of this type, an inductive energy transmission interface with the corresponding transmission components can also be provided on the electronic device 3 and the energy storage device 5.

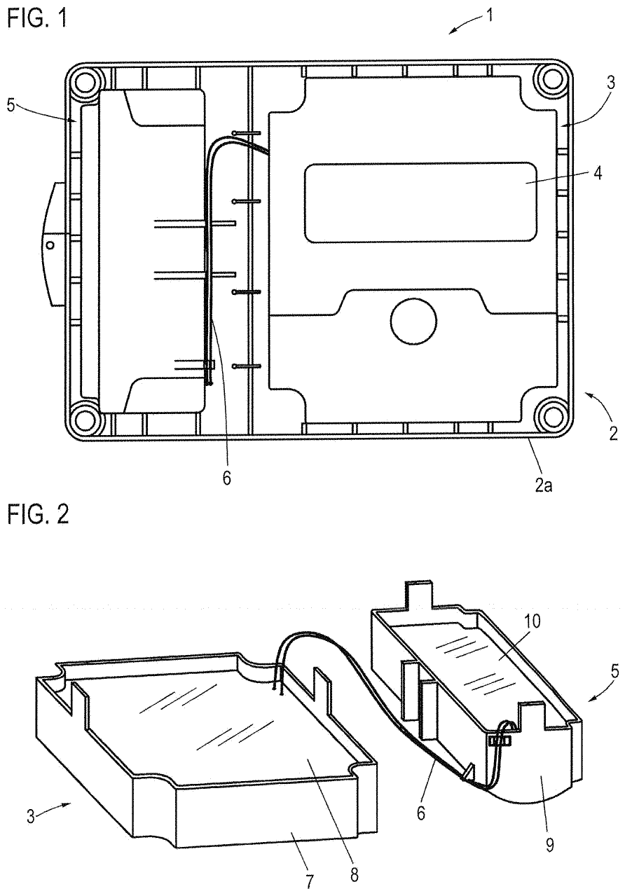

FIG. 2 shows the relevant elements, namely, the electronic device 3 and the energy storage device 5, separately from the underside, wherein it is clear from this depiction that the electronic device 3 has a potting housing 7 in which the associated components are arranged and which is potted with a potting compound 8. Similarly, the energy storage device 5 also has a potting housing 9 in which the storage cells or storage modules are accommodated and which is also filled with a potting compound 10. The two-core cable connection 6 is connected to the associated connection poles of the electronic device 3 and the energy storage device 5, and is also potted in the respective potting compound 8, 10 with the associated terminals or rather line ends. As a result, a complete media seal is provided both on the part of the electronic device 3 and the energy storage device 5, as well as on the part of the cable connection 6, which is of course equipped with an associated media-resistant casing made of plastics material, etc.

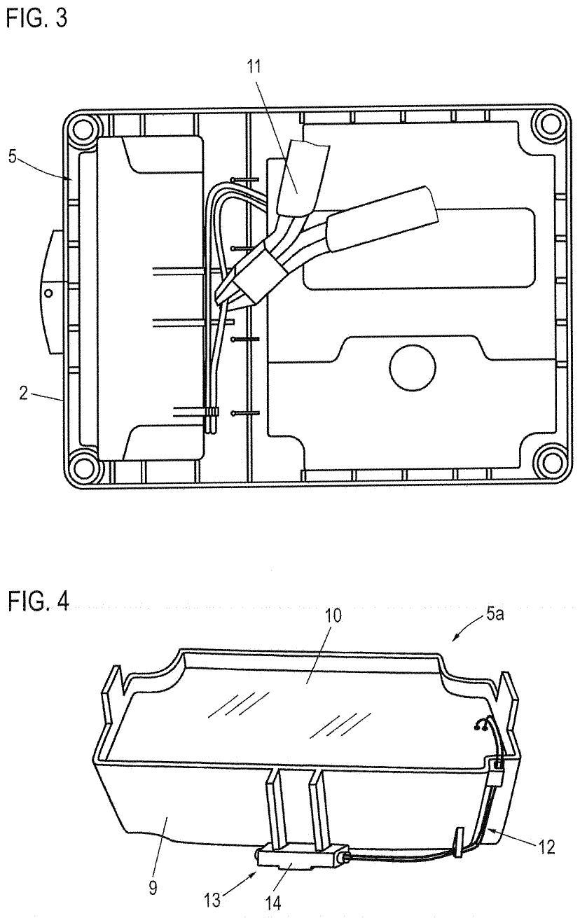

Let us assume, now, that the energy storage device 5 has to be replaced, either because it is defective or because its storage capacity is too low. This is done by disconnecting the cable connection 6, see FIG. 3, by means of a simple cutting tool 11; i.e., the cable is cut through in a simple manner so that the energy storage device 5 which is defective or has to be replaced can be removed from the housing 2.

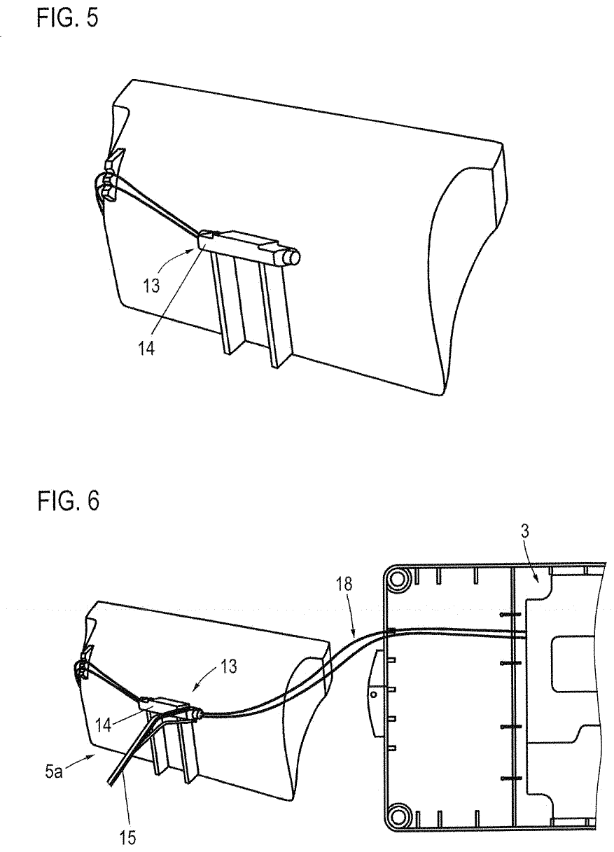

FIGS. 4 and 5 show a new, fully functional energy storage device 5a which, in an identical manner in the example shown, has a potting housing 9 in which the storage cells or storage module are accommodated and which is filled with a potting compound 10. The geometry of the new energy storage device 5a corresponds substantially or completely to the geometry of the energy storage device which is to be replaced, so that the new energy storage device 5a can be positioned appropriately.

The new energy storage device 5a has a cable section 12 which passes out of the potting compound 10, to which cable section a connecting device 13 in the form of an insulation-displacement connector 14 is already connected in a preconfigured manner at origin.

Contact to the electronic device 3 or rather the cable section 18 thereof, which remains there after cutting through the cable connection 6, is then made by means of this connecting device 13 or rather this insulation-displacement connector 14. The two cables or strands are plugged into the insulation-displacement connector 14, after which it is pinched accordingly with a tool 15 (see FIG. 6). A fixed cable connection which, depending on the configuration of the connecting device 13, is media-tight again and thus protects the connection point is formed.

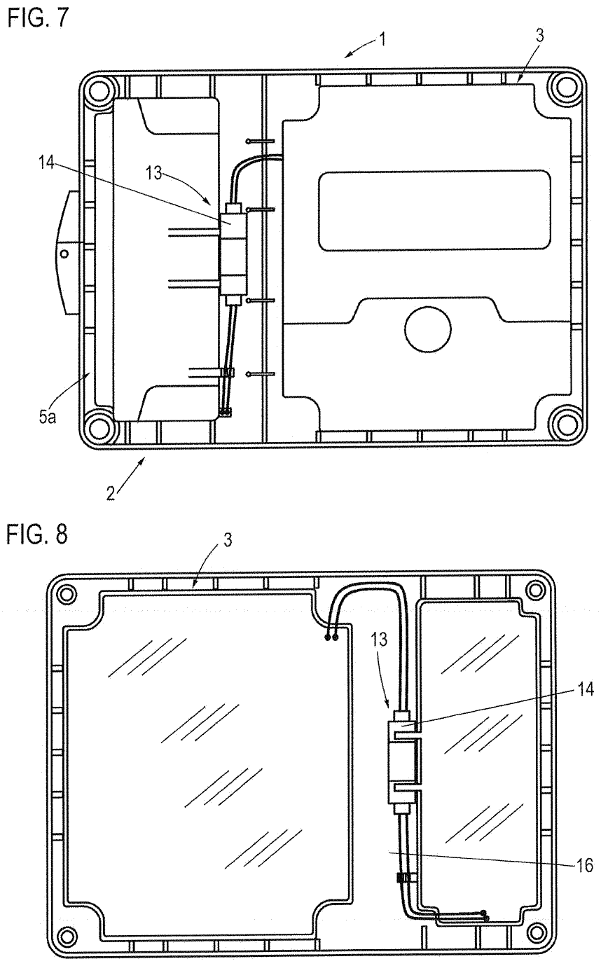

FIG. 7 then shows the arrangement of the electronic unit 1 of the fluid meter which is similar to the one from FIG. 1, however in this case the new energy storage device 5a is installed or rather inserted in the housing 2. It is apparent that the connecting device 13 is well placed inside the housing 2, as also shown in FIG. 8 in which the housing 2 is shown with the second housing half 2b, and therefore the electronic device 3 and the new energy storage device 5a can thus be seen from the underside. It is apparent that the connecting device 13, i.e. the insulation-displacement connector 14, is located on the underside of the housing shell 2b which, in relation to the assembly position, forms the upper housing cover.

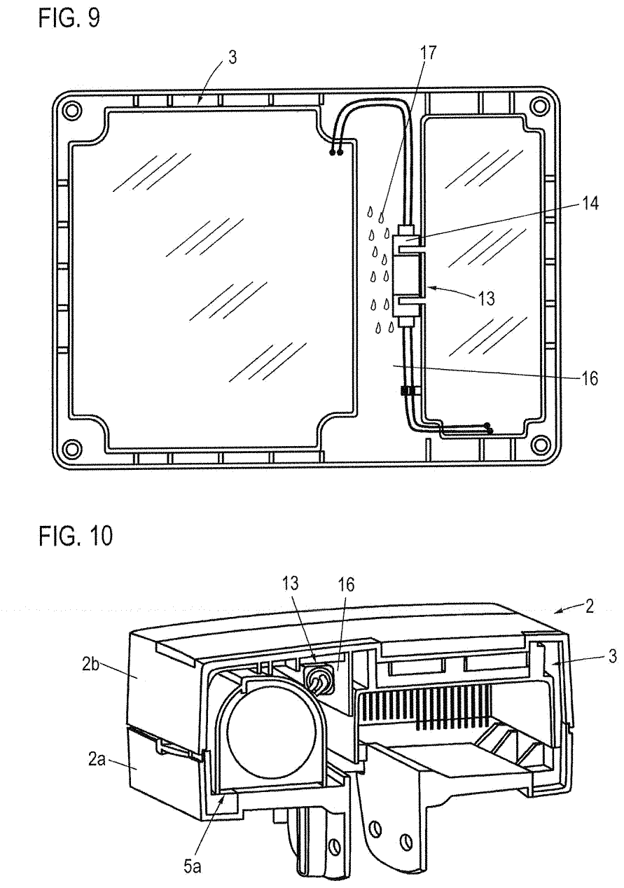

If the connecting device 13 already provides a sufficient media seal, associated with a corresponding corrosion protection of the cable connection which takes place therein, etc., no further measures are necessary with regards to an additional sealing of the connecting device 13. If the connecting device 13 does not necessarily guarantee this or if it is still necessary due to reasons of regulation, FIG. 9 shows the possibility of likewise potting the connecting device 13, which is accommodated in the corresponding housing region 16, in this region with a potting compound 17, as depicted by the droplet symbols in FIG. 9. This means that the appropriate liquid or paste potting compound is introduced in this section, so that the connecting device 13 is completely embedded therein and thus is definitively sealed thereafter.

Additionally or alternatively, it is also possible, see FIG. 10, to arrange the connecting device 13 in the housing 2 or rather in a housing region 16 in such a way that in the assembly position, i.e. when the fluid meter is reassembled under water, the connecting device 13 forms in a region in which an air bubble forms if there is an ingress of liquid, i.e. water, into the housing 2. Owing to the geometry of the housing part 2b, despite the ingress of water, the displaced air gathers in the upper region of the housing part 2b, consequently also thus in the housing region 16 in which the connecting device 13 is accommodated, such that a kind of air cushion forms which accommodates and protects the connecting device 13, so that in turn the high protection class is guaranteed despite the battery being replaced.

As a result, the fluid meter is in turn fully protected and fully operational in a submerged assembly, with even protection against flooding and the like being guaranteed.

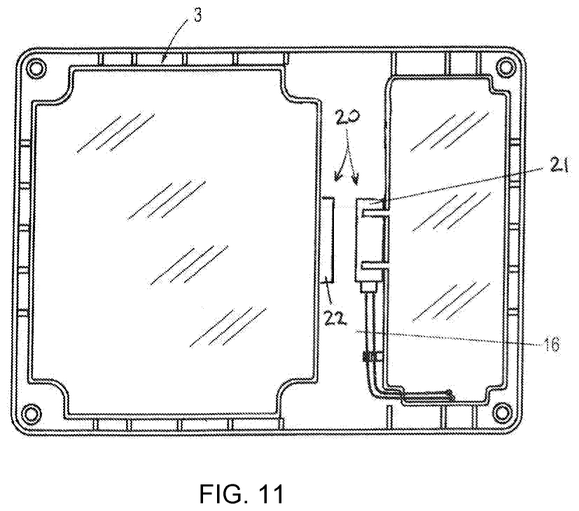

With reference to FIG. 11, the energy transfer from the energy storage device 5, 5a to the electronic device 3 may also be effected by way of a wireless power system 20, preferably, by inductive coupling. For that purpose, the energy storage device 5 carries a transmitter antenna 21. The electronic device 3 is provided with a receiver antenna 22. While the coupling devices, i.e., the antennas 20, 21, are illustrated as being separately carried on the electronic device 3 and on the energy storage device 5, respectively, they are preferably fully integrated into their respective housings, or potting housings, and/or they may be potted together with them. Inductive coupling for wireless energy transmission is sufficiently known in the art so that a specific description may be dispensed with.

The invention thus enables a simple replacement of an energy supply device, wherein the electronic unit 1 is designed in a very simple manner, with no specific sealant having to be provided thereon in order to seal the inside of the housing. This is because a more trouble-free and secure operation is guaranteed owing to the complete potting of the electronic device 3 and the energy storage device 5 or respectively 5a and, in the case of replacement, optionally also the connecting device 13.

Furthermore, in the event of the energy storage device 5a being replaced, this modular concept also offers the possibility to also couple an electronic device 3 of a fluid meter with a different type of battery. For example, a very compact electronic device 3 of a domestic water meter can be used by adding a larger D cell in the battery compartment, even for an industrial water meter with a higher energy requirement, but without restrictions on installation space.

If an inductive energy transmission, i.e. a wireless energy transmission, is intended, then only the energy storage device 5 has to be replaced, as has already been explained previously. In this case, it is not necessary to carry out any additional contacting or sealing measures on the part of the connecting device 13 etc. so that the fluid meter 1 is subsequently fully functional and ready for use again. In this case too, owing to the complete potting of the two devices involved, it is not necessary to provide any separate sealing measures on the housing 2, which can also be configured in a very simple manner in this case.

The following is a list of reference numerals used in the above description of the invention with reference to the drawing figures:
1 Electronic unit
2 Housing
2a Housing shell
2b Housing shell
3 Electronic device
4 Display device
5 Energy storage device
5a Energy storage device
6 Cable connection
7 Potting housing
8 Potting compound
9 Potting housing
10 Potting compound
11 Cutting tool
12 Cable section
13 Connecting device
14 Insulation-displacement connector
15 Tool
16 Housing region
17 Potting compound
18 Cable section
20 Wireless power system, inductive energy transmission interface
21 Transmitter antenna
22 Receiver antenna

1. A fluid meter with an electronic unit, the fluid meter comprising:
a housing;
an electronic device and an energy storage device disposed in said housing;
said energy storage device being associated with, and configured to supply, said electronic device;
said electronic device and said energy storage device being potted separately in a potting compound; and
a cable connection or an inductive energy transmission interface coupling said energy storage device with said electronic device.

2. The fluid meter according to claim 1, wherein said cable connection has one end embedded in the potting compound of said electronic device and one end embedded in the potting compound of said energy storage device.

3. The fluid meter according to claim 1, wherein said cable connection is fluid-resistant.

4. A replacement energy storage device for a fluid meter according to claim 1 and for replacing an energy storage device that is already present in the fluid meter, the replacement energy storage device comprising:
at least one storage cell accommodated in a potting housing;
a cable section that is routed to the outside of the potting housing, or an inductive energy transmission interface component arranged in the potting housing;
wherein said at least one storage cell and an end of the cable connection that is located in the potting housing, or the energy transmission interface component are potted with a potting compound;
a connecting device connected on the cable section and configured for connecting to a cable section of the electronic device of the fluid meter which remains connected to the electronic device after the energy storage device to be replaced has been removed.

5. The energy storage device according to claim 4, wherein the connecting device is an insulation-displacement connector.

6. A method of replacing an energy storage device of a fluid meter, the method comprising:
providing a fluid meter according to claim 1; and
replacing the energy storage device of the fluid meter with a replacement energy storage device according to claim 4.

7. The method according to claim 6, which comprises disconnecting a cable connection which connects the potted electronic device and the potted energy storage device, wherein a cable section remains on the electronic device, and subsequently connecting the connecting device at the end of the cable section of the replacement energy storage device to the remaining cable section on the electronic device.

8. The method according to claim 7, which comprises potting the connecting device with a potting compound after the cable section of the replacement energy storage device is connected to the remaining cable section on the electronic device.

9. The method according to claim 8, which comprises inserting the connecting device into a housing area that is subsequently filled with the potting compound.

10. The method according to claim 8, which comprises arranging a housing around the connecting device and subsequently filling the housing with the potting compound.

11. The method according to claim 7, which comprises arranging the connecting device in a region inside the housing of the fluid meter in which an air bubble forms in an assembly position in a fluid.

12. A fluid meter, comprising:
a potted electronic device disposed in a potting housing;
a potted energy storage device disposed in a potting housing, said energy storage device being a replacement energy storage device; and
a cable connection having a first cable section connected to said energy storage device, a second cable section connected to said electronic device, and a connecting device connecting said first and second cable sections to one another.

13. The fluid meter according to claim 12, wherein the connecting device is potted with a potting compound.

14. The fluid meter according to claim 13, wherein the connecting device is arranged in a housing region which is filled with the potting compound.

15. The fluid meter according to claim 13, wherein a housing is arranged around the connecting device, and the housing is subsequently filled with a potting compound.

16. The fluid meter according to claim 12, wherein the connecting device is arranged in a region inside the housing of the electronic unit in which an air bubble forms in an assembly position under fluid.
